(19) United States
(12) Patent Application Publication
(10) Pub. No.: US 2017/0301441 A1
(43) Pub. Date: Oct. 19, 2017

(54) Compositions Including Magnetic Materials

(71) Applicant: Simon Fraser University, Burnaby (CA)

(72) Inventors: Bonnie GRAY, Vancouver (CA); Daniel B. LEZNOFF, Vancouver (CA); Jasmine L. KORCOK, Burnaby (CA); Ajit KHOSLA, New Westminister (CA)

(21) Appl. No.: 15/636,413

(22) Filed: Jun. 28, 2017

Related U.S. Application Data
(63) Continuation of application No. 14/529,014, filed on Oct. 30, 2014.
Application No. 14/529,014 is a continuation of application No. 12/772,090, filed on Apr. 30, 2010, now abandoned.
(60) Provisional application No. 61/288,244, filed on Dec. 18, 2009.

(51) Int. Cl. H01F 1/055; H01F 1/147; H01F 1/058; H01F 1/057; G03F 7/32; G03F 7/004; G03F 7/20; G03F 7/16; G03F 7/038; G03F 7/38

(52) U.S. Cl. CPC H01F 1/0551; H01F 1/14791; H01F 1/14733; H01F 1/058; H01F 1/0571; G03F 7/38; G03F 7/0047; G03F 7/2004; G03F 7/168; G03F 7/162; G03F 7/0385; G03F 7/325

(57) ABSTRACT

Compositions including hard magnetic photoresists, soft photoresists, hard magnetic elastomers and soft magnetic elastomers are provided.

### TECHNICAL FIELD

The present invention relates to compositions including magnetic particles and compositions including magnetic nanoparticles.

### BACKGROUND

The magnitude of a permanent magnet's magnetic field is proportional to its saturation magnetism, Mₛ, which is the magnetization of a material when its magnetic moments are fully aligned with the applied external field, and its coercivity, which is the ability of the permanent magnet to retain its magnetization in the presence of an external demagnetizing field. Magnetization is the magnetic moments per unit volume in a material (emu/cm³) and is also measured in per mass unit (emu/g). Remnant magnetization is the magnetization remaining in a magnetic material once the external demagnetizing field has been turned off.

Coercivity, which is measured in Oersted (Oe), is used to distinguish between hard and soft magnetic materials. Hard and soft magnetic materials have applications in many different products including: motors, generators, electromagnets, transformers, signal transfer devices, speakers, sensors, analog data storage devices and digital data storage devices, for example.

### SUMMARY

There is provided herein a composition including: a photoresist; and hard magnetic particles dispersed in the photoresist to provide a micropatternable hard magnetic photoresist.

There is further provided herein a method of fabricating a hard magnetic photoresist including: agitating hard magnetic particles in a photoresist; and spinning the hard magnetic particles and the photoresist onto a substrate.

There is still further provided herein a composition including: an elastomer; and hard magnetic particles dispersed in the elastomer to provide a micromoldable hard magnetic elastomer.

There is further provided herein a method of fabricating a hard magnetic elastomer including: dispersing hard magnetic particles in a solvent; adding elastomer and agitating; adding curing agent and agitating; removing air bubbles; and heating to form solid film.

There is still further provided a composition including: a photoresist; and soft magnetic nanoparticles dispersed in the photoresist to provide a micropatternable hard magnetic photoresist.

There is still further provided a composition including: a photoresist; and soft magnetic particles dispersed in the elastomer to provide a micromoldable soft magnetic elastomer.

### DRAWINGS

The following figures set forth embodiments of the invention in which like reference numerals denote like parts. Embodiments of the invention are illustrated by way of example and not by way of limitation in the accompanying figures.

FIG. 1 shows fabrication steps for micropatterning of a photoresist composition;

FIG. 2 is a graph showing a spin curve for a hard magnetic photoresist;

FIG. 3 shows examples of different nanoparticles dispersed in SU-8;

FIG. 4 is an image of micromolded bar magnets;

FIG. 5 is an image of micromolded disc magnets;

FIGS. 6, 7 and 8 are SEM images of products fabricated using soft magnetic elastomers;

FIG. 9 is a graph showing microactuator deflection characteristics of micromolded cantilevers of FIG. 8;

FIG. 10 is a SEM image of an array of micromagnets fabricated using a hard magnetic elastomer;

FIG. 11 is a graph showing a typical M vs. H hysteresis loop at 300 K between −20 kOe and +20 kOe;

FIG. 12 shows the fabrication process steps for SU-8 micromold preparation; and

FIG. 13 shows the fabrication process steps for a hard magnetic elastomer.

### DETAILED DESCRIPTION OF EMBODIMENTS

Embodiments of the present invention provide compositions including hard magnetic particles, compositions including hard magnetic nanoparticles and compositions including soft magnetic nanoparticles. Hard magnetic materials are typically referred to as those magnetic materials having coercivities of approximately 100 Oe and above. In general, magnetic materials having higher coercivity are stronger magnets. Magnetic materials having different strengths are suitable for different applications.

Nanoparticles include one dimension that is less than or equal to 100 nm. Particles include one dimension that is less than or equal to 100 microns. It will be appreciated by a person skilled in that the term “particles” as used herein includes nanoparticles.

Nanoparticles may be spheres, flakes, rods, tubes, wires, core-shell or any other shape in which at least one dimension is less than or equal to 100 nm. It will be appreciated by a person skilled in the art that although at least one dimension is 100 nm or less, other dimensions of the nanoparticles may be bigger, such as 1000 nm or 1 mm, for example.

Examples of hard magnetic particles and nanoparticles include: FeC, CoFe, CoFeZn, Ni_{0.5}Co_{0.5}Fe₂O₄, Zn_{0.5}Co_{0.5}Fe₂O₄, Zn_{0.5}Ni_{0.5}F, NdFeB, CoFe₂O₄, NiFe₂O₄, ZnFe₂O₄, Ni_{0.5}Co_{0.5}Fe₂O₄, Zn_{0.5}Co_{0.5}Fe₂O₄, Zn_{0.5}Ni_{0.5}Fe, SrFe₁₂O₁₉, MQFP or combinations thereof. MQFP is NdPrCeFeB alloy having a dimension of 5 to 6 microns. The NdPrCeFeB alloy may be crushed or milled. MQFP is also known as MQP-12-D50, or S-powder, and is manufactured by Magnequench™

Hard magnetic materials are capable of producing and maintaining relatively high magnetic fields by themselves without the aid of external sources of energy such as an external magnetic field, for example. The intrinsic coercivity in neodymium-boron-iron is 24000 Oe, samarium-cobalt is 8700 Oe, and Alnico has 700 Oe. Table 1 shows the coercivities of a selection of further hard magnetic materials.

TABLE 1
Coercivities of some typical hard magnetic materials.

| Material | Name | Coercivity (Oe) |
|---|---|---|
| CoFe₂O₄ | cobalt iron oxide | 900 |
| ZnFe₂O₄ | zinc ferrite | |
| Ni_{0.5}Co_{0.5}Fe₂O₄ | Cobalt nickel ferrite | 286 |
| Zn_{0.5}Co_{0.5}Fe₂O₄ | Cobalt zinc ferrite | 286 |
| BaFe₁₂O₁₉ | Barium Ferrite | 3600 |
| SrFe₁₂O₁₉ | Strontium Hexaferrite | 6440 |
| NdFeB | Neodymium-iron-boron | 12000 |
| MQFP | Magnequench ™ | 5260 |
| CoFeV | Vicalloy (cobalt-iron- | 453 |
| | vanadium wrought) | |
| PtCo | Platinum cobalt | 4322.83 |
| Aluminium | Alnico | 1000 |
| Nickel Cobalt | | |

In one embodiment, compositions including hard magnetic particles and photoresists are provided. In another embodiment, compositions including hard magnetic nanoparticles and photoresists are provided.

Photoresists are materials that polymerize in response to exposure to an appropriate wavelength of light, such as ultraviolet (UV) light, for example. Photoresists may be used in microlithography processes for making miniaturized electronic components such as computer chips and integrated circuits, for example. Generally, in these processes, a thin coating of film of a photoresist is first applied to a substrate material. When making integrated circuits, silicon wafers are a common substrate material. The coated substrate is then baked to evaporate any solvent in the photoresist and to fix the coating onto the substrate. The photoresist coated on the substrate is next subjected to an image-wise exposure to radiation. The radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is optionally baked, and then treated with a developer solution to dissolve and remove either the radiation exposed (positive photoresist) or the unexposed areas of the photoresist (negative photoresist). Typically, the photoresist comprises a polymer, photoacid generator, solvent, and may further comprise additives such as basic quenchers, surfactants, dyes, crosslinkers, and the like. Some commercially available photoresists include: KMPR™, manufactured by MircoChem and photoresists of the Shipley Series.

Examples of polymers for use in photoresists include: polymethyl (meth)acrylate (PDMS), polymethylglutarimide, phenol-formaldehyde resins (Novolac) and epoxy-based resins (SU-8). Examples of photoacid generators for use in photoresists include sulfide type or onium type compounds for the photoacid generator. For example, the photoacid generator may be one or more compounds selected from diphenyl iodide hexafluorophosphate, diphenyl iodide hexafluoroarsenate, diphenyl iodide hexafluoroantimonate, diphenyl p-methoxyphenylsulfonium triflate, diphenyl p-toluenylsulfonium triflate, diphenyl p-isobutylphenylsulfonium triflate, diphenyl p-t-butylphenylsulfonium triflate, triphenylsulfonium hexafluorophosphate, triphenylsulfonium hexafluoroarsenate, triphenylsulfonium hexafluoroantimonate, triphenylsulfonium triflate, dibutylnaphthylsulfonium triflate, phthalimidotrifluoromethane sulfonate, dinitrobenzyltosylate, n-decyl disulfone, or naphthylimido trifluoromethane sulfonate. Examples of solvents for use in photoresists include: xylenes and methyl ethyl ketone (MEK), for example. Solvents having a lower degree of toxicity, good coating, and solubility properties are typically used.

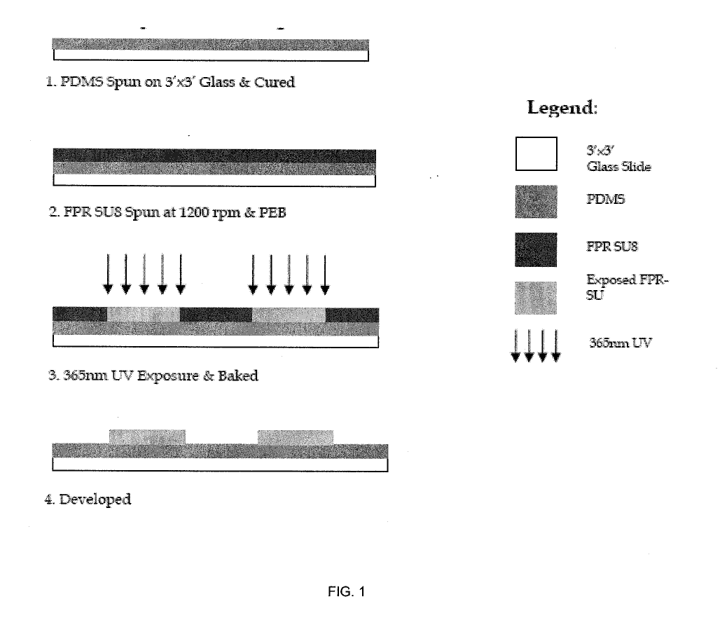

Referring to FIG. 1, fabrication steps for micropatterning of a photoresist composition are generally shown. The fabrication method is known in the art, however, the photoresist composition includes: a ferromagnetic photoresist (FPR) composition including SU-8, which is a negative tone photoresist that cures where it is exposed to ultraviolet (UV) light, and hard magnetic material that is dispersed throughout the SU-8. The hard magnetic material may be hard magnetic particles, hard magnetic nanoparticles or a combination thereof.

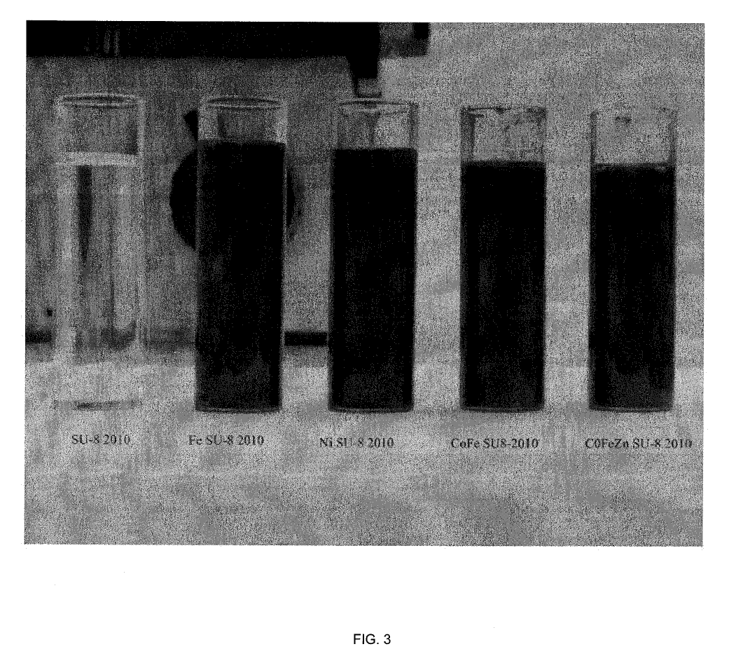

In one embodiment, the hard magnetic particles are MQFP. In another embodiment, the hard magnetic particles are nanoparticles including: FeC, CoFe, CoFeZn, Ni_{0.5}Co_{0.5}Fe₂O₄, Zn_{0.5}Co_{0.5}Fe₂O₄, Zn_{0.5}Ni_{0.5}F, NdFeB or combinations thereof. FIG. 3 shows examples of different nanoparticles dispersed in SU-8 with a ratio of 20% weight of nanoparticles.

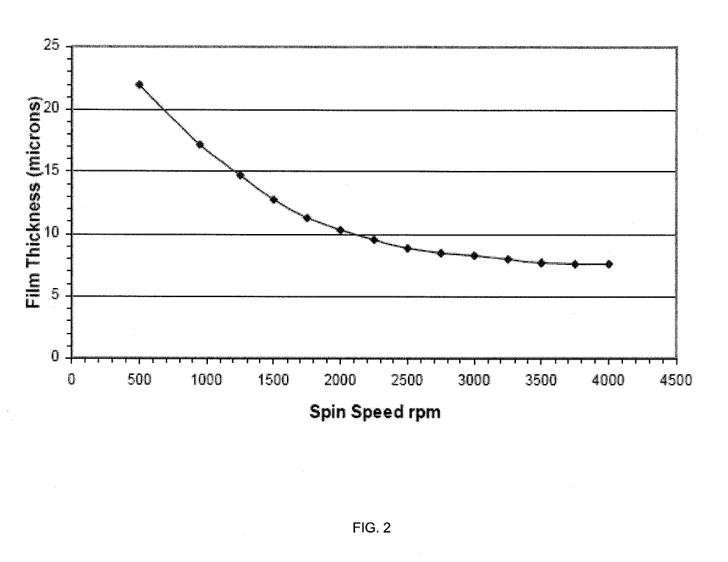

Referring back to FIG. 1, at step 1, PDMS is spun onto a glass slide. At step 2, FPR SU-8 is spun at 1200 rpm and PEB (Post Exposure Bake) is performed. A spin curve illustrating step 2 is shown in FIG. 2. At step 3, the FPR SU-8 is exposed to 3.365 nm UV light and baked. At step 4, the FPR is developed.

A method of fabricating a hard magnetic photoresist composition includes: 1) ultrasonically agitating hard magnetic particles in photoresist; 2) spinning the result of step 1 on the substrate; and 3) perform micropatterning using a method that is known in the art such as the method of FIG. 1, for example. In one embodiment, 3 grams of hard magnetic particles are agitated using a 750 Watt ultrasonic processor in 12 grams of SU-8 2010 photoresist in step 1 and the spin curve of FIG. 2 is applied. In this embodiment, the weight percentage of hard magnetic particles is 20% of the SU-8 photoresist.

In one example, hard magnetic particles are first dispersed ultrasonically by providing 3 grams in 12 grams of methyl ethyl ketone and then ultrasonically dispersing in 12 grams of SU-8 for 30 seconds. The composition is then heated at 45° C. to 50° C. until a similar viscosity to that of undoped SU-8 2010 is achieved. This example allows processing of the hard magnetic photoresist composition to proceed in the same way as normal SU-8 photoresists.

The hard magnetic photoresist compositions may be applied to substrates. For example, photoresist coatings are often used in the semiconductor industry. Suitable substrates include, without limitation, silicon, silicon substrate coated with a metal surface, copper coated silicon wafer, copper, aluminum, polymeric resins, silicon dioxide, metals, doped silicon dioxide, silicon nitride, tantalum, polysilicon, ceramics, aluminum/copper mixtures; gallium arsenide and other such Group III/V compounds, PMMA, Polystyrene and metals including gold, for example.

In a further embodiment, compositions including hard magnetic particles and photoresists are provided. In still a further embodiment, compositions including hard magnetic nanoparticles and photoresists are provided.

Elastomers are polymeric materials having the property of elasticity. A “thermoplastic elastomer” is a polymeric material having at least some crosslinking that is non-covalent in nature. A thermoplastic elastomer (TPE) has the ability to deform under stress and return to something approximating its original conformation upon removal of that stress. In addition, thermoplastic elastomers are processable as a melt at elevated temperatures.

Examples of elastomers include: Acrylic (PMMA), Acrylonitrile butadiene styrene (ABS), Polyamide (PA or Nylon), Liquid Crystal Polymer (LCP), Polyvinyl chloride (PVC) Polyester, Polystyrene (PS). Examples of thermosetting elastomers include Polydimethylsiloxane (PDMS), styrenic block copolymers, polyolefin blends, elastomeric alloys (TPE-v or TPV), thermoplastic polyurethanes, thermoplastic copolyester, thermoplastic polyamides, RTV polymers (room temperature vulcanizing: type of rubber that hardens through chemical means instead of heat), and combinations thereof.

Examples of TPE products that come from block copolymers group include Styroflex™ (BASF®), Kraton™ (Shell® chemicals), Pellethane™ (Dow® chemical), Pebax™, Arnitel™ (DSM®), Hytrel™ (Du Pont®) and more. There are many commercial products of elastomer alloys, these include Dryflex ([VTC TPE Group]), Santoprene (Monsanto Company), Geolast (Monsanto), Sarlink (DSM), Forprene (So.F.ter. spa), Alcryn (Du Pont) and Evoprene (AlphaGary).

Examples of thermoplastic elastomers include: ethylene-propylene copolymers, hereinafter called EPM, ethylene-propylene-diene terpolymers, hereinafter called EPDM, acrylonitrile-butadiene rubber, styrene-butadiene rubber, isobutene-isoprene rubber, styrene-ethylene/styrene-butadiene block copolymers, butyl rubber, isobutylene-p-methylstyrene copolymers or brominated isobutylene-p-methylstyrene copolymers or natural rubber. Also mixtures of elastomers may be used. Preferably, the elastomer olefinic elastomer such as EPM or EPDM.

Examples of thermoplastic polymers include thermoplastic polyolefin homo- and copolymers or blends thereof. For example, homopolymers of ethylene or propylene, copolymers of ethylene and propylene, copolymers of ethylene and an alpha-olefin comonomer with 4-20 carbon atoms or copolymers of propylene and an alpha-olefin comonomer with 4-20 carbon atoms. In case of a copolymer, the content of propylene in said copolymer is preferably at least 75% by weight.

Still further examples of thermoplastic polymers include thermoplastic polyolefine elastomers (TPO's), polyamides, polycarbonate, polyesters, polysulfones, polylactones, polyacetals, acrylonitrile-butadiene-styrene (ABS) resins, polyphenylene oxide (PPO), polyphenylene sulfide (PPS), styrene-acrylonitrile (SAN) resins, polyimides, styrene maleic anhydride (SMA) and aromatic polyketones.

It will be appreciated by a person skilled in the art that any combination of thermoplastic polymers may also be used.

In one embodiment, the elastomer includes a curing agent. Any suitable curing agent may be used. Examples of curing agents include sulphur, sulphurous compounds, metal oxides, maleimides, phenol resins, siloxane compounds, peroxides, or combinations thereof. In another embodiment, additional optional ingredients are included. For example, accelerators, catalysts, activators, or combinations thereof.

In one embodiment the compositions including hard magnetic material dispersed in an elastomer may be fabricated to be UV or photo patternable by adding photoinitatiors such as Benzophenone, 2-hydroxy-2-methylpropiophenone, for example. Non-conductive, non magnetic UV patteranable silicone products (WL-5000 series) are also available (Dow Corning (USA)).

A method of fabricating a hard magnetic elastomer composition includes: 1) dispersing hard magnetic particles in a solvent capable of dissolving silicone, such as heptane or toluene, for example; 2) adding elastomer, manually stirring then ultrasonically agitating; 3) adding curing agent, manually stirring then ultrasonically agitating; 4) placing liquid product of step 3 in a vacuum or at low temperature to remove air bubbles; and 5) heating to form solid film.

In one example, step 1 includes dispersing 1.5 grams of particles in 5 grams of Heptane using ultrasound waves for 30 seconds; step 2 includes adding 6 grams of PDMS elastomer, first manually stirring for 3 minutes and then ultrasonically agitating for 5 minutes; step 3 includes adding the curing agent of PDMS (ratio 1:10) and again manually stirring for 3 minutes and ultrasonically agitating for 5 minutes; step 4 includes placing the liquid product of step 3 at a temperature of 0° C. for 15 minutes; and step 5 includes heating at 70° C. for 2 hours.

In one embodiment, the hard magnetic particles are MQFP by Magnequench™

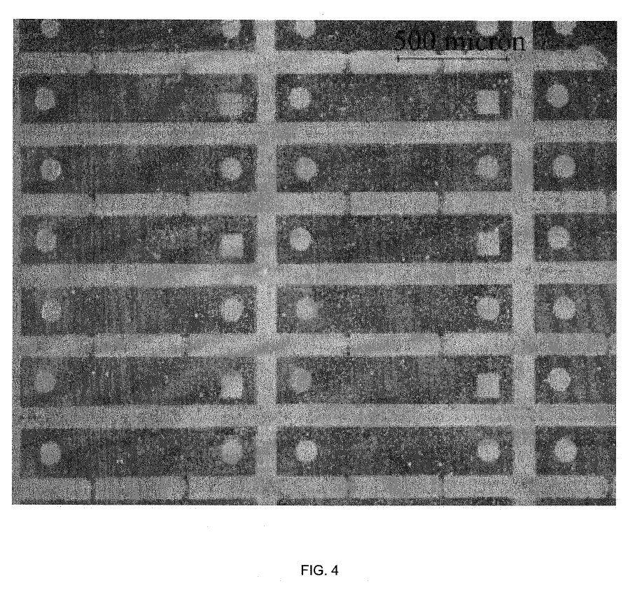

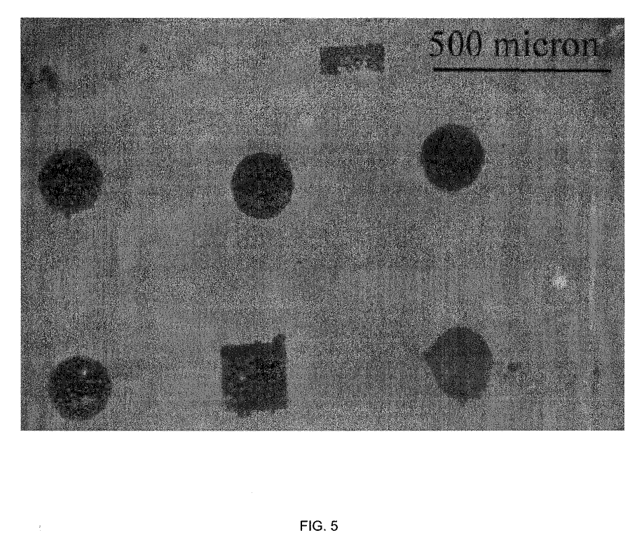

Referring to FIGS. 4 and 5, examples of micromolded hard magnets fabricated using a composition of MQFP by Magnequench™ and an elastomer are shown. FIG. 4 shows bar micromagnets and FIG. 5 shows disc micromagnets. The height of the micromagnets shown is 200 microns and they are fabricated using a softlithography method. The micromagnets may be mounted on magnetic substrates and non-magnetic substrates. These and other micromagnets fabricated using hard magnetic elastomer compositions have applications in micromotors and microgenerators, for example.

In another embodiment, the hard magnetic particles are nanoparticles including: CoFe₂O₄, NiFe₂O₄, ZnFe₂O₄, Ni_{0.5}Co_{0.5}Fe₂O₄, Zn_{0.5}Co_{0.5}Fe₂O₄, Zn_{0.5}Ni_{0.5}Fe, SrFe₁₂O₁₉, or combinations thereof.

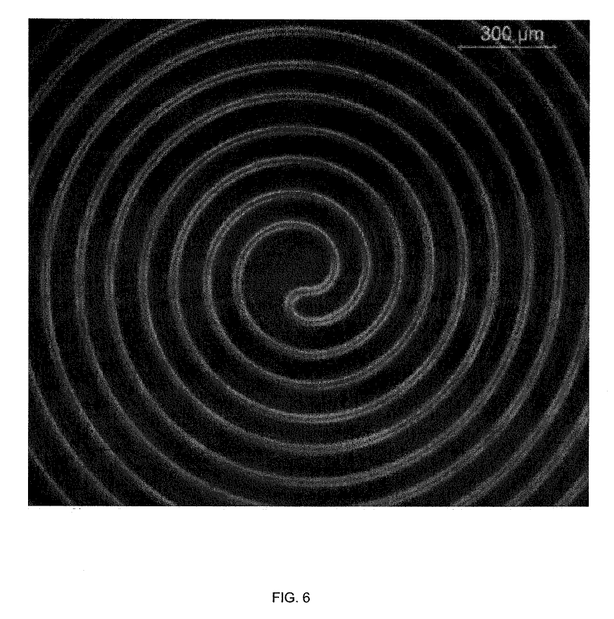

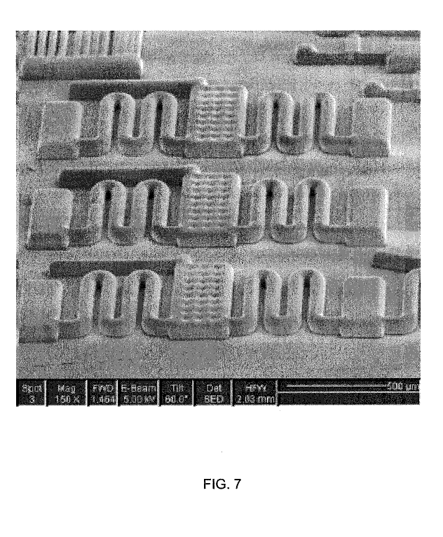

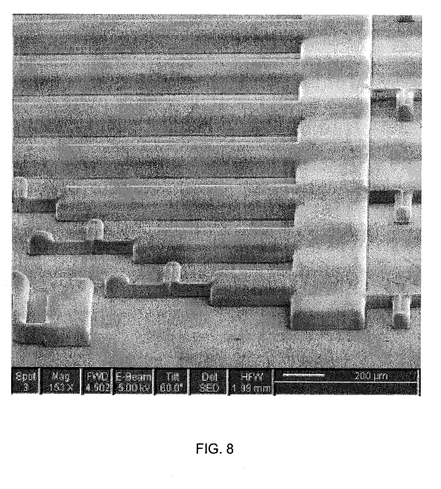

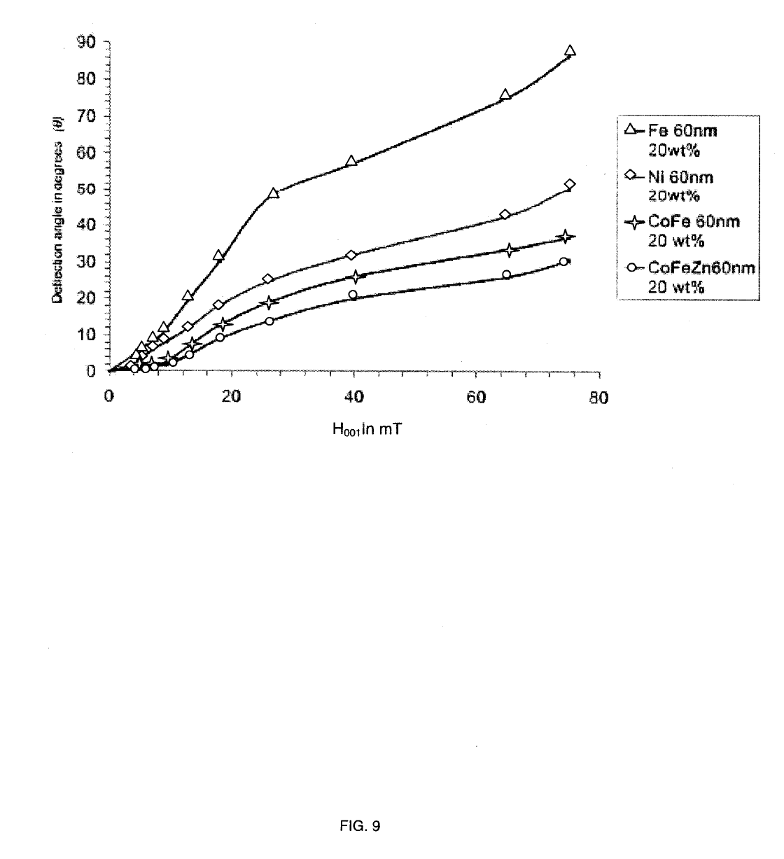

Referring to FIGS. 6, 7 and 8, examples of some products fabricated using soft magnetic elastomer compositions are shown. FIG. 6 is an optical micrograph of a micromolded coil fabricated using a soft magnetic elastomer composition. FIG. 7 is a Scanning Electron Microscopy (SEM) image of a micromolded bridge fabricated using a soft magnetic elastomer composition. FIG. 8 is a SEM image of micromolded cantilevers fabricated using a soft magnetic elastomer composition. FIG. 9 shows microactuator deflection characteristics of the micromolded cantilevers of FIG. 7. These characteristics indicate that the magnetic elastomers can be remotely actuated and controlled on application of an external magnetic field.

Examples of soft magnetic nanoparticles include: nickel iron alloy, which has a trade name of Permalloy and a coercivity of 0.1 to t Oe; nickel iron molybdenum copper, which has a trade name of Mu-metal; nickel iron molybdenum, which has a trade name of supermalloy and a coercivity of 0.002 Oe; iron silicon aluminum, which has a trade name of sendust and a coercivity of approximately 20 Oe; and iron silicon, which has a coercivity of 0.03 to 1 Oe.

For both the magnetic photoresist composition and magnetic elastomer composition embodiments, the particles and/or nanoparticles are dispersed throughout a polymer matrix. Some examples of dispersion methods include ultrasonics, ball/bead milling, shear mixing, functionalizing, or a combination thereof. Typically, the nanoparticles are mixed manually prior to application of the dispersion method.

Ultrasonics includes High Frequency Ultrasonics and Low Frequency Ultrasonics. In high frequency ultrasonics the operating frequency is ˜42-50 kHz, in which an ultrasonic probe is immersed into the composite. Significant heat can be generated by the process which can result in curing or hardening of the photoresists or elastomers. Therefore, the probe may be operated in pulse mode (eg. 10 seconds on/15 seconds off cycle) which helps avoid this issue. Generally this is a fast process/method. In low frequency ultrasonics the operating frequency is ˜20-24 kHz, in which the composite is placed in an ultrasonic bath and is agitated for a certain time depending on the type of nanoparticles. This process is generally takes more time than High Frequency Ultrasonics.

Ball milling includes providing a rotary cylinder along with balls, which are typically plastic rather than iron, is used to break up the clumps of nanoparticles. However, the technique is not widely used at research level and tends to break the nanoparticles of high aspect ratio. Bead milling uses micro beads instead of balls.

Shear mixing allows direct dispersion of nanoparticles in the polymer or photoresist matrix. The nanoparticles aggregates are forced apart by high speed shear mixing. The viscosity of the solvent/polymer matrix does not allow the nanoparticles to re-aggregate. It can be problematic to use a magnetic stirrer for mixing magnetic materials so electric motor operated stirrers were used which have a rotating spindle or a “T” shaped structure immersed in the composite.

The functionalizing method includes altering or functionalizing the surface of nanoparticles with, for example, surfactants that aid their dispersion within a polymer.

As will be appreciated by a person skilled in the art, the magnetic particles and nanoparticles may alternatively be doped for both the magnetic photoresist composition and magnetic elastomer composition embodiments, the particles and/or nanoparticles are dispersed throughout a polymer matrix.

### Example 1

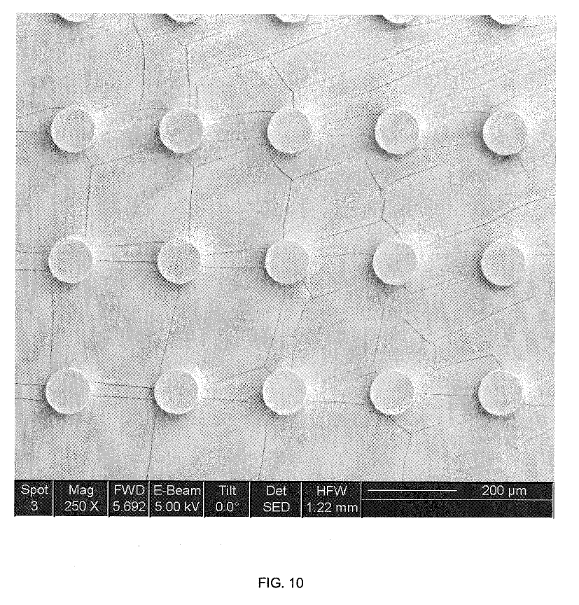

Referring to FIG. 10, a SEM image of an array of fabricated micromagnets is shown. In order to fabricate the micromagnets of FIG. 10, a micromold was first fabricated.

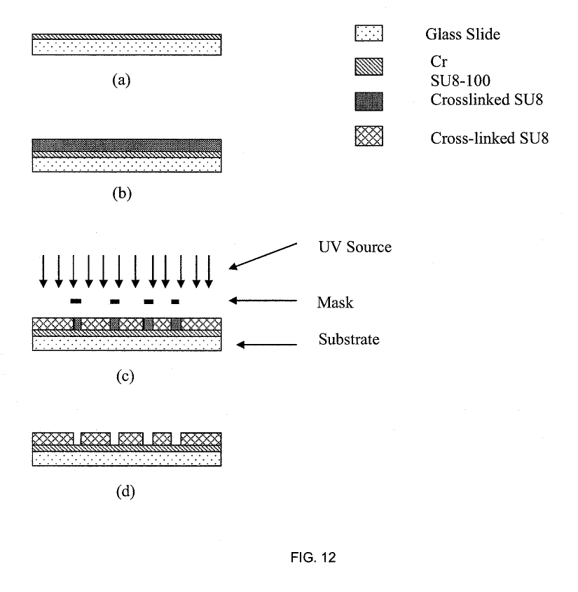

Referring to FIG. 12, glass slides 3″×3″ square and 1 mm thick were used as substrates which were first cleaned in 100% Micro 90 Detergent (purchased from International Products Corporation, USA) using ultrasonic agitation for 5 minutes and then rinsed with de-ionized (DI) water, acetone, isopropyl alcohol (IPA) and DI water. Substrates were blow dried using nitrogen followed by dehydration baking for 20 minutes at 120° C. in a convection oven and cooling to room temperature. A 25 nm thick chrome layer was sputtered on each glass substrate to act as an adhesion promoter for the SU-8 100, as shown in FIG. 12(a). A 100 μm thick layer of SU-8 10, which is a negative tone epoxy based UV patternable photoresist, was spin coated (at 2250 RPM) on top of the adhesion layer of each substrate, followed by soft baking at 90° C. for 80 minutes and cooling to room temperature, as shown in FIG. 12(b). Desired structures were patterned using photolithographic UV exposure through a photomask for 60 seconds, as shown in FIG. 12(c). Full crosslinking of the SU-8 100 was achieved by a post-exposure bake at a temperature of 60° C. for 65 minutes (ramp rate: 300° C./hr) followed by cooling to room temperature. The structural layer on each substrate was then developed in SU-8 Developer (Microchem™) for 90 seconds in an ultrasonic bath, as shown in FIG. 12(d).

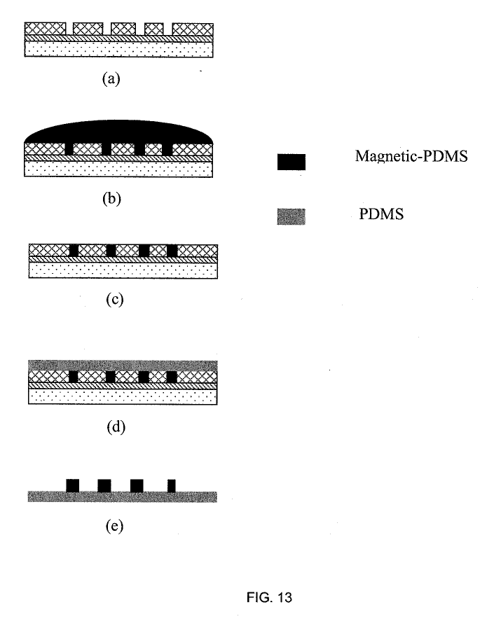

Following fabrication of the micromold, MQFP-12-5 hard magnetic powder manufactured by Magnequench™ (Toronto, Ontario, Canada), was first manually stirred in PDMS base elastomer for 5 minutes and then paced in an ultrasonic bath operating at frequency of 42 kHz in pulse mode (10 seconds on/15 seconds off) for 4 hrs prior to adding curing agent Dimethy methylhydrogen siloxane. The base elastomer (Silicone monomer) and curing agent ratio was approximately 10:1 as recommended by the supplier (Dow Corning Inc. USA). The prepared composite was placed into a vacuum chamber for 30 minutes to remove air bubbles and then poured on to the micromold, as shown in FIG. 13(b), and degassed for ten minutes. Excess composite was scraped off using the Damascene-like process from the surface of the mold using surgical knife, as shown in FIG. 13(c). Undoped PDMS polymer was then poured on the surface and degassed, as shown in FIG. 13(d). Substrate was then kept on a hotplate at 75° C. for 1 hour and then peeled off from the mold, as shown in FIG. 13 (e).

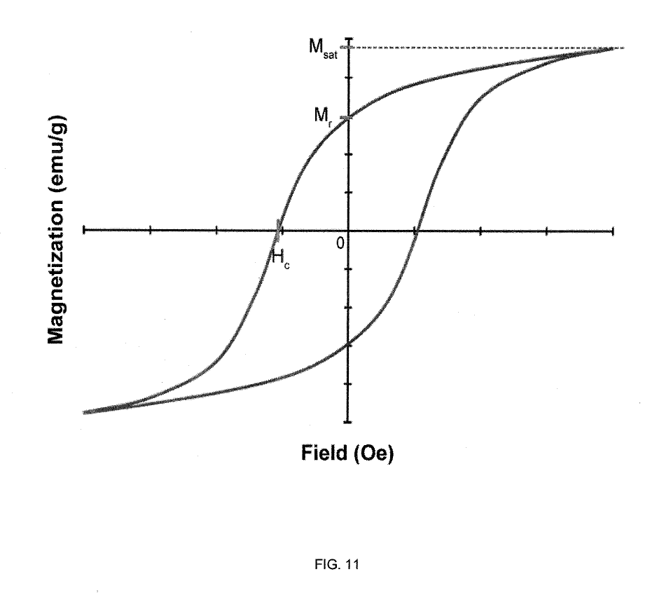

The magnetic properties of the micromolded permanent magnets shown in FIG. 10 were measured using a Quantum Design MPMS-XL-7S SQUID magnetometer. A typical M vs. H hysteresis loop at 300 K between −20 kOe and +20 kOe is shown in FIG. 11. The hysteresis loop was found to be quite reproducible; different samples from the same magnetic paste batch did not show much variation (Table 2), indicating that the MQFP particles were homogenously dispersed in PDMS matrix. The coercivity, H_{c}, was 5260±30 Oe, confirming that the properties of the magnetic powder was unchanged upon micromolding into the composite material since the pure 5-6 micron MQFP-12-5 powder has an H_{c}=5325 Oe; the pure powder also has a remanent magnetization, Mᵣ=80.68 emu/g. The remanent magnetization of the 75% w/w micromolded permanent magnets, Mᵣ, was 60.10 emu/g on average verifying the 75% w/w loading value of the magnetic powder into the micromolded permanent magnets.

TABLE 2
Coercivity and remanent magnetization of five different batches of the above
micromolded magnets (50 μm, height 30 μm micromolded magnets)

| Magnet | 1 | 2 | 3 | 4 | 5 |
|---|---|---|---|---|---|
| H_{c} (Oe) | 5245 | 5280 | 5260 | 5290 | 5225 |
| Mᵣ (emu/g) | 59.64 | 65.19 | 58.91 | 57.17 | 59.61 |

In this example, the micromold is fabricated out of SU-8, however, the micromold may alternatively be fabricated out of another material, such as a photoresist, metal, mica, glass, silicon wafers, plastics including PMMA and Plexiglas, cement, stones or rocks, for example. The micromold material should not be made of reactive organic solvents and elastomers.

Applications for hard magnetic photoresist compositions and hard magnetic elastomer compositions include: semiconductors, microelectromechanical systems (MEMS) such as microactuators, micromotors, microgenerators, bistable p-switches, sensing devices, microposistioning, telecommunications, low-frequency switches, magnetic isolaters, couplers, BioMEMS including separation of biomolecules immobilized on magnetic beads nanotubes, centrifugates, pumps, valves, microdevices or microassembly.

Specific embodiments have been shown and described herein. However, modifications and variations may occur to those skilled in the art. All such modifications and variations are believed to be within the scope and sphere of the present invention.

1. A composition comprising:
a photoresist; and
hard magnetic particles dispersed in the photoresist to provide a micropatternable hard magnetic photoresist.

2. A composition as claimed in claim 1, wherein said hard magnetic particles are NdPrCeFeB alloy.

3. A composition as claimed in claim 1, wherein said hard magnetic particles are nanoparticles.

4. A composition as claimed in claim 3, wherein said hard magnetic nanoparticles are selected from the group comprising: FeC, CoFe, CoFeZn, Ni_{0.5}Co_{0.5}Fe₂O₄, Zn_{0.5}Co_{0.5}Fe₂O₄, Zn_{0.5}Ni_{0.5}F or NdFeB.

5. A composition comprising:
an elastomer; and
hard magnetic particles dispersed in the elastomer to provide a micromoldable hard magnetic elastomer.

6. A composition as claimed in claim 5, wherein said hard magnetic particles are NdPrCeFeB alloy.

7. A composition as claimed in claim 5, wherein said hard magnetic particles are nanoparticles.

8. A composition as claimed in claim 7, wherein said hard magnetic nanoparticles are selected from the group comprising: CoFe₂O₄, NiFe₂O₄, ZnFe₂O₄, Ni_{0.5}Co_{0.5}Fe₂O₄, Zn_{0.5}Co_{0.5}Fe₂O₄, Zn_{0.5}Ni_{0.5}Fe or SrFe₁₂O₁₉.

9. A composition as claimed in claim 5, wherein said elastomer is a thermoplastic elastomer.

10. A method of fabricating a hard magnetic photoresist comprising:
agitating hard magnetic particles in a photoresist; and
spinning the hard magnetic particles and the photoresist onto a substrate.

11. A method as claimed in claim 10, wherein said hard magnetic particles are NdPrCeFeB alloy.

12. A method as claimed in claim 10, wherein said hard magnetic particles are nanoparticles.

13. A method as claimed in claim 12, wherein said hard magnetic nanoparticles are selected from the group comprising: FeC, CoFe, CoFeZn, Ni_{0.5}Co_{0.5}Fe₂O₄, Zn_{0.5}Co_{0.5}Fe₂O₄, Zn_{0.5}Ni_{0.5}F or NdFeB.

14. A method of fabricating a hard magnetic elastomer comprising:
dispersing hard magnetic particles in a solvent;
adding elastomer and agitating;
adding curing agent and agitating;
removing air bubbles; and
heating to form solid film.

15. A method as claimed in claim 14, wherein said hard magnetic particles are NdPrCeFeB alloy.

16. A method as claimed in claim 14, wherein said hard magnetic particles are nanoparticles.

17. A method as claimed in claim 16, wherein said hard magnetic nanoparticles are selected from the group comprising: CoFe₂O₄, NiFe₂O₄, ZnFe₂O₄, Ni_{0.5}Co_{0.5}Fe₂O₄, Zn_{0.5}Co_{0.5}Fe₂O₄, Zn_{0.5}Ni_{0.5}Fe or SrFe₁₂O₁₉.

18. A method as claimed in claim 14, wherein said solvent is heptane or toluene.

19. A composition comprising:
a photoresist; and
soft magnetic nanoparticles dispersed in the photoresist to provide a micropatternable hard magnetic photoresist.

20. A composition as claimed in claim 19, wherein said soft magnetic particles are selected from the group comprising: nickel iron alloy, nickel iron molybdenum copper, nickel iron molybdenum, iron silicon aluminum or iron silicon.

21. A composition comprising:
a photoresist; and
soft magnetic particles dispersed in the elastomer to provide a micromoldable soft magnetic elastomer.

22. A composition as claimed in claim 21, wherein said soft magnetic particles are selected from the group comprising: nickel iron alloy, nickel iron molybdenum copper, nickel iron molybdenum, iron silicon aluminum or iron silicon.
